(19) United States
(12) Patent Application Publication
(10) Pub. No.: US 2024/0069247 A1
(43) Pub. Date: Feb. 29, 2024

(54) WINDOW AND USE THEREOF

(71) Applicants: SCHOTT AG, Mainz (DE); SCHOTT Suisse SA, Yverdon-les-Bains (CH)

(72) Inventors: Frank Wolff, Mainz (DE); Ulf Brauneck, Yverdon-les-Bains (CH)

(73) Assignees: SCHOTT AG, Mainz (DE); SCHOTT Suisse SA, Yverdon-les-Bains (CH)

(21) Appl. No.: 18/453,730

(22) Filed: Aug. 22, 2023

(30) Foreign Application Priority Data
Aug. 22, 2022 (DE) 10 2022 121 125.8

(51) Int. Cl. G02B 1/11; G02B 5/20

(52) U.S. Cl. CPC G02B 1/11; G02B 5/20

(57) ABSTRACT

A window includes: a vitreous substrate pane forming a substrate, the substrate including at least one surface; and a coating disposed on the at least one surface of the substrate, wherein at least one of:
(a) the window within a wavelength range from 400 to 700 nm has an average transmittance τ_{avg,400 nm to 700 nm} of less than 15%, where τ_{avg,400 nm to 700 nm} is defined as

$${τ}_{a v ℊ , 400 n m - 700 n m} = \frac{{\int }_{400 n m}^{700 n m} τ d λ}{700 n m - 400 n m} ;$$

and
(b) at any wavelength the window has a spectral transmittance of less than 15%,
wherein the window at at least one wavelength within a wavelength range from 875 nm to 1600 nm has a transmittance of at least 75%.

### CROSS REFERENCE TO RELATED APPLICATIONS

This claims priority to German patent application no. 10 2022 121 125.8, filed Aug. 22, 2022, which is incorporated herein by reference.

### BACKGROUND OF THE INVENTION

### 1. Field of the Invention

The present invention relates to a window, and, more particularly, to a window pane having a coating.

### 2. Description of the Related Art

A window is understood to mean a construction in the form of a pane, including at least one pane made of a substrate material, wherein the material is transparent or has a minimum transmittance at least for selected wavelength ranges. The material usually includes amorphous materials, especially glasses. Coatings may be applied on one or both sides of the substrate pane, and these, depending on the characteristics, can influence both optical and mechanical properties of the window. Especially in the case of glasses, the applying of one or more suitable coatings can give the desired advantageous or even requisite properties for the respective use. For instance, the mechanical strength of glasses can be considerably increased by the applying of a suitable coating. For instance, correspondingly coated glass panes can have elevated scratch resistance, such that these can be used as windows even in applications in which elevated mechanical stresses have to be expected.

In principle, such windows can generally also be used as cover glasses for protection of components. For example, such cover glasses can also be used for protection of systems including a laser, for example for distance measurement in a vehicle.

For safety reasons, it may be advantageous for such cover glasses for systems including a laser to have only low transmittance in the visible spectral region.

Also known are filter glasses that have sufficiently high transmittance in the laser wavelength range and simultaneously only low optical transmittance, i.e. in the visible spectral region. In many cases, these optical filter glasses do not have sufficient mechanical and/or chemical stability that are demanded from cover glasses in the automotive sector. This is because the environment for such covers is harsh and includes, for example, not only mechanical stresses such as stonechipping but also car washes, moisture stress, temperature fluctuations, salt spray, insolation, especially in the case of use in the automotive sector.

Suitable “technical glasses”, i.e. vitreous materials that can already be used in windows without additional coatings, frequently do not have adequate filter properties.

There is thus a need for cover glasses for electronic components, especially those that include a laser, having good optical filter action and sufficient mechanical and chemical stability for use in automotive applications.

What is needed in the art is a window for use as cover glass that at least partially alleviates the aforementioned weaknesses of the prior art. What is also needed in the art is the use of such a window.

### SUMMARY OF THE INVENTION

The present invention relates generally to a window including at least one vitreous substrate pane having a coating and to the use thereof.

The present invention provides a window including a vitreous substrate pane and a coating disposed on at least one surface of the substrate. The window within a wavelength range from 400 to 700 nm has an average transmittance τ_{avg,400 nm to 700 nm} of less than 15%, optionally of less than 10%, where τ_{avg,400 nm to 700 nm} is defined as

$${τ}_{a v ℊ , 400 n m - 700 n m} = \frac{{\int }_{400 n m}^{700 n m} τ d λ}{700 n m - 400 n m} .$$

Alternatively or additionally, the window at any wavelength has a spectral transmittance of less than 15%, optionally less than 10%, optionally less than 5% and optionally less than 1%.

The transmittance of the window at at least one wavelength within a wavelength range from 875 nm to 1600 nm is at least 75%, optionally 80%, optionally at least 85%, optionally at least 90%, optionally at least 95%, further optionally at least 97%.

The substrate pane of the window includes a colored glass. This especially also includes the case that the substrate pane consists of a colored glass or has been formed from a colored glass.

By virtue of the use of a colored glass having the aforementioned transmittance properties in the visible spectral range, the resulting window is rendered sufficiently opaque to the human eye. It is thus impossible for a coincidental observer to be able to tell what is behind the composite. This gives rise to a homogeneous color impression. Moreover, any damage to the observer's eyes can be prevented.

The window is optionally configured such that the colored glass at at least one wavelength within the laser wavelength range that may be within a range from 875 nm to 1600 nm has a very high pure transmittance of at least 75%, optionally at least 80%, optionally at least 85%, optionally at least 90%, optionally at least 95%, further optionally at least 97%. In other words, the colored glass thus has sufficient transparency for a laser beam.

One embodiment envisages the use of a colored glass having the following glass composition in cation percent (cat %):
silicon 30-80, optionally 35-75, optionally 40-70
boron 0-20
aluminium 0-2
sodium 5-35, optionally 7.5-30, optionally 12-20,
   optionally 14-18
potassium 2-25, optionally 5-20, optionally 6-15
nickel 0-0.5
chromium 0-0.5
cobalt 0.03-0.5
with
Σsodium+potassium 15-50, optionally 20-45, optionally 25-30
Σnickel+chromium 0.1-0.5
and where the ratio of the sum total of sodium and potassium to the sum total of nickel and cobalt is as follows:

Σsodium+potassium/Σnickel+cobalt=70:1 to 200:1.

The glass optionally has a molar ratio of potassium cations to sodium cations in the range from 0.3:1 to 0.9:1, optionally in the range from 0.4:1 to 0.8:1, optionally in the range from 0.6:1 to 0.7:1

The expression “cation percent” refers to the relative molar proportion of the respective cations in the total cation content (in mol). As well as cations, the glass also contains anions. The anion content is accordingly reported in anion percent (anion %). The glass having the above-detailed composition contains, as anions, optionally O²⁻, F⁻, Br⁻, Cl⁻ and/or SO₄²⁻ anions. The proportion of O²⁻ ions is optionally at least 50 anion %, optionally at least 70 anion %, optionally at least 90 anion %. In an optional embodiment, the proportion of O²⁻ ions is at least 98 anion % or even at least 99 anion %. In one embodiment, the entire glass is oxidic, i.e. the proportion of O²⁻ ions is 100 anion %.

In a further embodiment, the glass contains only a small proportion of halides (Cl⁻, F⁻ and/or I⁻). The proportion of halides is optionally not more than 3 anion %, optionally not more than 1 anion %. The glass is optionally free of halides. Other embodiments envisage a chloride content of at least 0.1 anion %, optionally at least 0.2 anion %, optionally at least 0.5 anion %, at least 1 anion %, at least 2 anion % or at least 3 anion %. In one embodiment, the glass has a chloride content in the range from 0.5 to 10 anion %, optionally in the range from 1 to 5 anion %.

An alternative embodiment envisages the use of a glass having the following glass composition in cation % as substrate:
silicon 40-80, optionally 50-70, optionally 60-70
boron 0-20, optionally 1-19, optionally 5 to 15
aluminium 0-25, optionally 2-20, optionally 5-12
sodium 2-22, optionally 3-20, optionally 4-18
potassium 0.1-10, optionally 1-8, optionally 2-5
chromium 0.05-0.5, optionally 0.1-0.4, optionally 0.15-0.3
cobalt 0.03-0.5, optionally 0.04-0.3, optionally 0.05-0.2
with
Σsodium+potassium=10-25, optionally 12-20, optionally 15-20
Σchromium+cobalt=0.15-0.55, optionally 0.17-0.5, optionally 0.19-0.4
and where the ratio of the sum total of sodium and potassium to the sum total of nickel and cobalt is as follows:

Σsodium+potassium/Σnickel+cobalt=25:1-150:1,optionally 30:1-125:1, optionally 40:1 to 90:1.

As well as cations, the glass also contains anions. The anion content is accordingly reported in anion percent (anion %). The glass having the above-detailed composition contains, as anions, optionally O²⁻, F⁻, Br⁻, Cl⁻ and/or SO₄²⁻ anions. The proportion of O²⁻ ions is optionally at least 50 anion %, optionally at least 70 anion %, optionally at least 90 anion %. In a particularly optional embodiment, the proportion of O²⁻ ions is at least 98 anion % or even at least 99 anion %. In one embodiment, the entire glass is oxidic, i.e. the proportion of O²⁻ ions is 100 anion %.

In a further embodiment, the glass contains only a small proportion of halides (Cl⁻, F⁻ and/or I⁻). The proportion of halides is optionally not more than 3 anion %, optionally not more than 1 anion %. The glass is optionally free of halides. Other embodiments envisage a chloride content of 0.1 anion %, optionally at least 0.2 anion %, optionally at least 0.5 anion %, at least 1 anion %, at least 2 anion % or at least 3 anion %. In one embodiment, the glass has a chloride content in the range from 0.5 to 10 anion %, optionally in the range from 1 to 5 anion %.

In a further embodiment, the colored glass has the following composition in % by weight:
SiO₂ 50-80, optionally 55-75, optionally 60-73
Al₂O₃ 0-10, optionally 1-8, optionally 2-6
B₂O₃ 0-15, optionally 2-10, optionally 3-8
   with
Li₂O 0-20, optionally 3-18, optionally 6-12
Na₂O 0-20, optionally 3-18, optionally 6-12
K₂O 0-25, optionally 1-20, optionally 5-13
BaO 0-10, optionally 1-8, optionally 3-5
CaO 0-10, optionally 2-6, optionally 3-5
MgO 0-10, optionally 2-6, optionally 3-5
ZnO 0-10, optionally 1-8, optionally 3-5
La₂O₃ 0-20, optionally 1-15, optionally 2-12, most optionally 5-10
TiO₂ 0-5, optionally 1-15, optionally 2-12
Cl 0-3, optionally 0.1-2, optionally 0.3-0.50
MnO₂ 1.0-5.0, optionally 1.5-4.5, optionally 2-4, most optionally 2.5-3,
Cr₂O₃ 0.2-3, optionally 0.5-2.5, optionally 0.7-2, most optionally 1-1.5 ΣNa₂O+K₂O+Li₂O=5-30, optionally 10-25, optionally 15-20.
   The glass composition optionally satisfies at least one of the following conditions:

ΣMnO₂+Cr₂O₃=2.7-8, optionally 3-7, optionally 3.5-5.5 and/or

MnO₂/CrO₃=1.5:1 to 12.5:1, optionally 1.6:1 to 10:1, optionally 1.7:1 to 7.5, optionally 1.9:1 to 4:1.

The substrate has a thickness of at least 0.5 mm and at most 12 mm. In an advantageous embodiment, the thickness of the substrate is in the range from 0.5 to 6 mm, optionally in the range from 2 mm to 6 mm, optionally in the range from 2 to 4 mm. Corresponding substrate thicknesses ensure sufficiently high strength.

The substrate is in the form of a pane and has two sides, referred to hereinafter as top side and bottom side. The top side is understood here to mean the side of the substrate that forms the front side of the window in use when the substrate is used as part of a window. The top side is thus the side of the substrate that forms the side facing the observer in the case of use as a window. The bottom side is understood to mean the side of the substrate that forms the reverse side in use when the coated substrate is used as window for covering an electronic component, and hence is the side of the substrate that faces the electronic component.

The window includes, on at least one of the two sides, at least one layer including an oxide and/or nitride and/or oxynitride of a metal and/or semimetal. The layer optionally takes the form of a coating or part of a coating. The window optionally has a coating on at least the front side or top side of the colored glass in use. In some embodiments, the window according to the present invention, optionally in addition to the coating on the front side in use, has a further coating on what is called the reverse side in use, which is especially an antireflection coating and/or a hydrophobic and/or oleophobic coating and/or anti-frost coating and/or anti-fog coating and/or heatable coating, especially a coating that fulfills the function of an antireflection coating and/or a heatable coating.

The coating may generally have a further function, for example as antireflection coating, as anti-scratch coating, as optical coating, for example with color reflection, as climate protection coating, as easy-to-clean coating, as hydrophobic, oleophobic, anti-frost, anti-fog and/or heatable coating. The coating may be executed as a multilayer coating, i.e. include multiple layers. It is possible that the coating fulfills various functions simultaneously; for example, an optical coating for creation of antireflection effect also has an uppermost layer executed, for example, as an anti-fog or hydrophobic coating.

The coating is optionally a multilayer antireflection coating formed from multiple layers or layers having different refractive indices. In this case, there are layers with relatively high refractive indices alternating with layers having lower refractive indices. The layers of low refractive indices include silicon oxide, for example. In a further embodiment, the layers having low refractive indices are based on silicon oxide with a proportion of aluminium. In an advantageous embodiment, the layers of low refractive index have a ratio of molar amounts of silicon to aluminium according to the following relationship:

n(Al)/(n(Si)+n(Al))>0.02,

where n(Al) denotes the molar amount of aluminium and n(Si) the molar amount of silicon. It has been found that, surprisingly, the addition of aluminium, for example aluminium oxide, imparts distinctly higher resistance to scratching and abrasion to the silicon oxide layers of low refractive index, which are soft by comparison with the silicon nitride layers of high refractive index. In one embodiment, the n(Al)/(n(Si)+n(Al)) ratio is greater than 0.05, optionally greater than 0.1. It has been found here to be advantageous when the n(Al)/(n(Si)+n(Al)) ratio is less than 0.8, optionally less than 0.5, optionally less than 0.25.

The layers of relatively high refractive index optionally contain a silicide, oxide or nitride. Silicon nitride is particularly suitable for the layers of high refractive index.

An optional deposition method used for the layers of the antireflection coating is sputtering, especially magnetron sputtering. In this context, reactive sputtering is also particularly advantageous, since, in this case, both the silicon oxide for the layers of low refractive index and the silicon nitride used with an option for layers of high refractive index can be produced with the same target. The changeover to the different layer materials can be effected in a simple manner by changing the process parameters, especially the composition of the process gas.

The coating optionally has a thickness of at least 125 nm and at most 2500 nm, optionally at most 1500 nm. It has been found that, surprisingly, a corresponding antireflection layer provides long-lived scratch resistance even with comparatively low layer thicknesses. Thus, the antireflection coating, in an optional execution, has a total layer thickness in the range from 200 nm to 400 nm. Optional layer thicknesses are in the range from 250 nm to 300 nm. By way of comparison, typical scratch-resistant coatings or hardcoats generally have a thickness of more than 1 μm.

By choice of the properties of the substrate, for example glass composition or glass thickness, and also by choice of the coating, it is possible to flexibly adapt the window to the respective field of use and the requirements thereof.

In one embodiment, the window at at least one wavelength within a range from 875 nm to 1600 nm has spectral reflectance ρ_{λ} of not more than 14%, optionally not more than 12%, optionally or even not more than 10%. The reflectance of a wavelength X is defined here as follows:

ρ_{λ}=Pᵣ/P₀

where Pᵣ is the reflected power and P₀ the incident power.

Alternatively or additionally, the window within a range from 875 to 1600 nm has average spectral reflectance ρₐᵥₑ of not more than 14%, optionally not more than 12%, optionally not more than 10%, where average spectral reflectance ρₐᵥₑ is the arithmetic average of the individual spectral reflectances ρ_{λ} within the wavelength range of interest.

Reflectance is optionally determined here for a measurement angle between 0° and 60°, optionally for a measurement angle between 0° and 70°. Thus, the window in one advantageous configuration has low reflectivity over a wide angle range.

Alternatively or additionally, spectral reflectance ρ_{λ} at at least one wavelength within a wavelength range from 875 nm to 1600 nm is at least 2 percentage points, optionally at least 4 percentage points, optionally at least 6 percentage points, lower than the corresponding reflectance of the uncoated substrate.

Alternatively or additionally, the average spectral reflectance ρₐᵥₑ of a surface of the window for measurement angles within a range from 0° to 45° within a wavelength range between 1530 nm and 1570 nm, optionally 1540 nm and 1560 nm, is not more than 4%, optionally not more than 2% and optionally not more than 1%. In one embodiment, the average spectral reflectance ρₐᵥₑ in these wavelength ranges for a measurement angle of 60° is not more than 7%, optionally not more than 5%, optionally not more than 4% and optionally not more than 3%.

In one embodiment, the average spectral reflectance ρₐᵥₑ of a surface of the window for measurement angles within a range from 0° to 45° within a wavelength range between 880 nm and 930 nm, optionally 890 nm and 920 nm, is not more than 4%, optionally not more than 3%, optionally not more than 2% and optionally not more than 1%. In one embodiment, the average spectral reflectance ρₐᵥₑ within these wavelength ranges for a measurement angle of 60° is not more than 7%, optionally not more than 5%, optionally not more than 4% and optionally not more than 3%.

In a further embodiment, the average spectral reflectance ρₐᵥₑ of a surface of the window for measurement angles in the range from 0° to 45° within a wavelength range between 1300 nm and 1340 nm, optionally 1310 nm and 1330 nm, is not more than 4%, optionally not more than 2% and optionally not more than 1%. In one embodiment, the average spectral reflectance ρₐᵥₑ in these wavelength ranges for a measurement angle of 60° is not more than 7%, optionally not more than 5%, optionally not more than 4% and optionally not more than 3%.

The window has average transmittance T_{avg}, where average transmittance T_{avg} is the arithmetic average of the transmittances of the individual wavelengths within the wavelength range specified. In one embodiment, the average transmittance, T_{avg}, in the wavelength range between 1530 nm and 1570 nm, optionally 1540 to 1560 nm, is at least 90%, at least 91%, optionally at least 93% and optionally at least 96% for a measurement angle of 0°. Alternatively or additionally, the transmittance, T_{avg}, in this wavelength range, at a measurement angle of 45°, is at least 89%, optionally at least 90%, at least 92% and optionally at least 95%. In one embodiment, the window within the wavelength range mentioned, at a measurement angle of 60°, has a transmittance, T_{avg}, of at least 87%, optionally at least 88%, optionally at least 90% and optionally of at least 93%. The window in the abovementioned wavelength range may even have a transmittance, T_{avg}, at a measurement angle of 70° of at least 84%, optionally at least 85%, optionally at least 87% and optionally at least 90%.

High transmittance in the range from 1530 nm to 1570 nm makes the window particularly suitable for use in combination with a laser having a central wavelength within the wavelength range stated, especially at 1550 nm. The transmittance is largely independent of angle in spite of the optical interference coating applied.

Alternatively or additionally, the window has an average transmittance T_{avg} within the wavelength range between 890 nm and 930 nm, optionally 890 to 920 nm, of at least 91%, optionally at least 93% and optionally at least 96% for a measurement angle of 0°. Alternatively or additionally, the transmittance, T_{avg}, in this wavelength range at a measurement angle of 45° is at least 89%, optionally at least 90% and optionally at least 95%. In one embodiment, the window within the wavelength range mentioned, at a measurement angle of 60°, has a transmittance, T_{avg}, of at least 87%, optionally at least 88%, optionally at least 90% and optionally of at least 93%. The window within the abovementioned wavelength range may even have a transmittance, T_{avg}, at a measurement angle of 70°, of at least 84%, optionally at least 85%, optionally at least 87% and optionally at least 90%.

High transmittance in the range from 890 nm to 930 nm makes the window particularly suitable for use in combination with a laser having a central wavelength within the wavelength range stated, especially at 905 nm. Here too, transmittance is largely independent of angle.

Alternatively or additionally, the window has an average transmittance T_{avg} within the wavelength range between 1300 nm and 1340 nm, optionally 1310 to 1330 nm, of at least 91%, optionally at least 93% and optionally at least 96% for a measurement angle of 0°. Alternatively or additionally, the transmittance, T_{avg}, in this wavelength range, at a measurement angle of 45°, is at least 89%, optionally at least 90% and optionally at least 95%. In one embodiment, the window within the wavelength range mentioned, at a measurement angle of 60°, has a transmittance, T_{avg}, of at least 87%, optionally at least 88%, optionally at least 90% and optionally of at least 93%. The window within the abovementioned wavelength range may even have a transmittance, T_{avg}, at a measurement angle of 70° of at least 84%, optionally at least 85%, optionally at least 87% and optionally at least 90%.

High transmittance in the range from 1300 nm to 1340 nm makes the window particularly suitable for use in combination with a laser having a central wavelength within the wavelength range stated, especially at 1310 nm and/or 1320 nm. Here too, transmittance is largely independent of angle.

It has been found to be advantageous when the window or optical interference coating is such that it has only a minor polarization split, if any. In one embodiment, therefore, the difference in spectral transmittance between s- and p-polarized light, ΔT_{s-p,pol}, of the window at at least one wavelength in the range between 875 nm and 1600 nm, optionally between 880 nm and 1600 nm, and at least one measurement angle from 30 to 60°, is less than 3 percentage points, optionally less than 2 percentage points and more optionally less than 1 percentage point. In one embodiment, the difference in spectral transmittance between s- and p-polarized light, ΔT_{s-p,pol}, of the window at at least one measurement angle in the range from 30° to 60° and in at least one of the wavelength ranges of 890 nm to 910 nm, 1310 nm to 1330 nm and/or 1540 nm to 1560 nm is less than 3 percentage points, optionally less than 2 percentage points and optionally less than 1 percentage point.

Advantageously, the vitreous substrate includes a glass having a coefficient of thermal expansion in the range between 3*10⁻⁶/K and 14*10⁻⁶/K for temperatures in the range from −30° C. to 70° C. The coefficient of thermal expansion is optionally in the range from 5*10⁻⁶/K to 12*10⁻⁶/K, optionally in the range from 7*10⁻⁶/K to 11*10⁻⁶/K. The value reported is the nominal average coefficient of thermal expansion according to ISO 7991, determined by static measurement. Because of its coefficient of thermal expansion, the glass has high thermal cycling stability.

Such a configuration as described above may be advantageous especially when large temperature fluctuations occur in use of an electronic component protected by the window. This is because, in this case, the coefficients of thermal expansion of substrate and coating are matched to one another and there can thus be no mechanical stresses that would be high enough to cause delaminations between coating and substrate and/or within the coating. Thus, the coating has good adhesion on the substrate, which has an advantageous effect on the mechanical stability of the window.

In particular, the good mechanical stability of the layer composite, i.e. of the bond between substrate and coating, and also of the layer composite, i.e. of the individual sublayers within the coating, can also be shown by the Bayer test. Thus, the window, after performance of the Bayer test according to modified test standard ASTM F735-11 (modified Bayer test with 8000 cycles and loading with 2 kg of fused alumina (Al₂O₃) rather than SiO₂; the fill height is 2 cm), has a haze value elevated by comparison with the haze value of the window measured before the Bayer test by not more than 4%, optionally not more than 2% and optionally not more than 1%. The haze value was determined according to ASTM D1003-95 and is a measure of cloudiness. Surface defects such as scratches, for example, lead here to an increase in the haze value.

The window, for angle ranges from 0° to 30°, has a phototopic reflection color, i.e. reflectivity weighted by the eye sensitivity curve according to CIE 1931, with color coordinates x in the range from 0.20 to 0.4 and y in the range from 0.20 to 0.4, optionally x 0.25 to 0.33 and y 0.23 to 0.33. This causes the window to appear black to the observer. In an optional embodiment, the window has the abovementioned color coordinates for angles in the range from 0° to 45° or even from 0° to 60°.

A window according to embodiments may especially be used as cover glass, especially as cover glass for a laser, for example of a laser as part of a LIDAR system, or for an imaging system, especially for an imaging system of a device for 3D surveying of the environment or for measurement of speed.

### BRIEF DESCRIPTION OF THE DRAWINGS

FIGS. The above-mentioned and other features and advantages of this invention, and the manner of attaining them, will become more apparent and the invention will be better understood by reference to the following description of embodiments of the invention taken in conjunction with the accompanying drawings, wherein:

FIG. 1 is a schematic diagram of a cross section through a first embodiment;

FIG. 2 is a schematic diagram of a cross section through a second embodiment;

FIG. 3 is a schematic diagram of a cross section through a third embodiment with a further coating on the reverse side in use;

FIG. 4 is the reflection spectra of a first exemplary embodiment at different recording angles;

FIG. 5 is the reflection spectra of a second exemplary embodiment;

FIGS. 6 and 7 are the reflection spectra of a third exemplary embodiment at different recording angles;

FIG. 8 is the reflection spectra of a fourth exemplary embodiment at different recording angles;

FIG. 9 is the reflection spectra of a fifth exemplary embodiment at different recording angles, in each case before and after the performance of a Bayer test;

FIGS. 10 and 11 are the reflection spectra of electromagnetic radiation with different polarization angles for a fifth exemplary embodiment;

FIGS. 12 and 13 are the reflection spectra of electromagnetic radiation with different measurement angles for a sixth exemplary embodiment; and

FIG. 14 is the angle-dependent shift in the reflection color of the sixth exemplary embodiment with reference to a CIE 1931 x-y diagram.

Corresponding reference characters indicate corresponding parts throughout the several views. The exemplifications set out herein illustrate embodiments of the invention, and such exemplifications are not to be construed as limiting the scope of the invention in any manner.

### DETAILED DESCRIPTION OF THE INVENTION

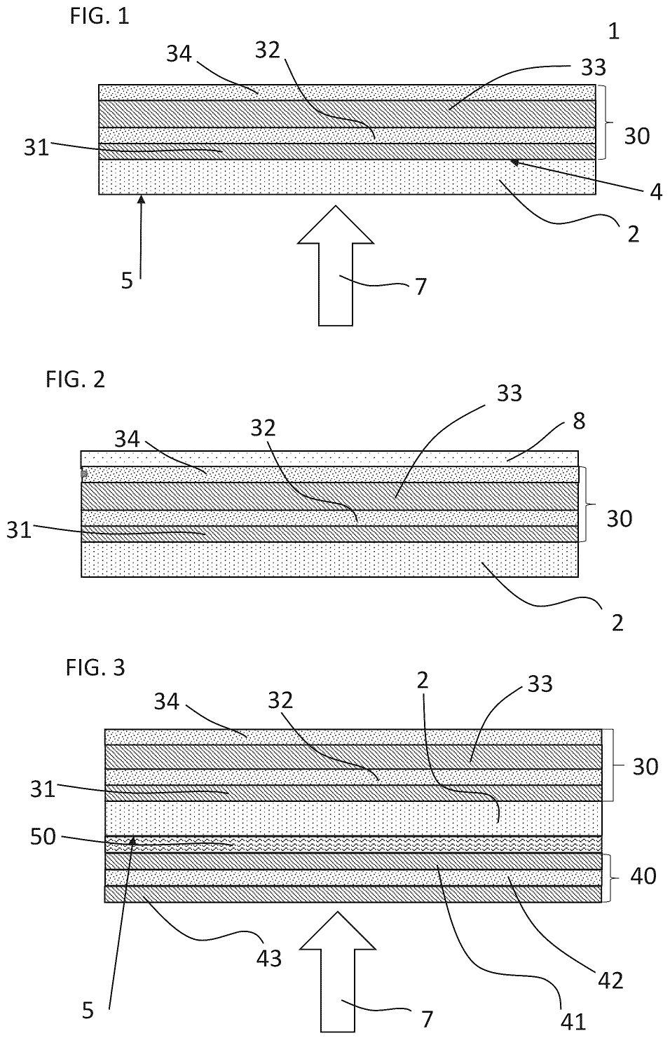

FIG. 1 shows a cross section through a schematic diagram of a window 1 in one embodiment. The window 1 has a colored glass as vitreous substrate pane 2, and a coating 30 deposited on the surface 4 of the substrate 2. The coating 30 has four layers in the example shown in FIG. 1. The coating includes at least one oxide, nitride and/or oxynitride of a metal and/or semimetal.

The coating 30 includes layers 34, 32 of low refractive index, and layers 31, 33 that have a higher refractive index. Layer 33 here contains at least one of the materials SiN, Si_{X}O_{y}N_{z}, SiₓAlO_{y}N_{z}, SiXN:H, SiₓN_{y}O_{z}:H and/or AlₓO_{y}N_{z}.

The embodiment shown in FIG. 1 is used to cover an electronic light emitting component. The electromagnetic radiation emitted is symbolized by the arrow 7 and enters through the window 1. The lateral face of the substrate 2 facing the component (given reference numeral 5 in FIG. 1) is referred to as bottom side or else as reverse side in use. The other lateral face 4 of the substrate is correspondingly referred to as top side or else as front side in use. In the embodiment shown in FIG. 1, the coating 30 has been applied to the top side 4 of the substrate 2.

The layer thickness of the coating 30 is in the range from 125 nm to 2500 nm, optionally in the range from 125 nm to 1500 nm. The penultimate layer 33 here has maximum layer thickness, optionally a layer thickness of at least 100 nm, optionally at least 150 nm and optionally at least 200 nm. The relatively high layer thickness of the hardcoat layer 33 here makes a crucial contribution to scratch resistance and mechanical strength both of the coating 30 and of the window 1. The uppermost layer 34 optionally has minimum layer thickness. In one embodiment, the layer thickness of layer 34 is less than 300 nm or even less than 100 nm.

The window 1 in a wavelength range from 400 to 700 nm has average transmittance τ_{avg,400 nm to 700 nm} of less than 15%, optionally of less than 10%, where τ_{avg,400 nm to 700 nm} is defined as

$${τ}_{a v ℊ , 400 n m - 700 n m} = \frac{{\int }_{400 n m}^{700 n m} τ d λ}{700 n m - 400 n m}$$

Alternatively or additionally, the window 1 at any wavelength has spectral transmittance of less than 10%, optionally less than 5% and optionally less than 1%.

FIG. 2 shows a schematic diagram of a window in a further embodiment. Here, the window, as well the coating 30 with the four individual layers 31, 32, 33, 34, has a further layer 8. Layer 8 here is not a layer of the optical interference coating 8, but may differ from coating 30 both in terms of its composition and in terms of its function. The exemplary embodiment shown in FIG. 2 is an “easy-to-clean” layer that has a contact angle for water of >105°.

FIG. 3 shows a further embodiment of a window 1. Here, the substrate 2, as well as an optical interference coating 30 with the individual layers 31, 32, 33, 34 on the front side 4 in use, has a further coating 40. The coating 40 includes the optical interference layers 41, 42, 43, and optionally the electrically conductive layer 50. Layers 41, 42, 43 form an antireflection coating and hence prevent backscatter of the emitted light 7. Layer 50 is a layer including or composed of indium tin oxide (ITO). Layer 50 has an area resistance in the range from 10 to 150 Ω/sq and has contacts (not shown) via which it can be connected to a power source. Layer 50 may thus fulfill the function of a heating layer.

Coating 40 has been applied to the bottom side 5 of the colored glass 2. It may fulfill the function, for example, of reducing reflections of the emitted light 7 before passage through the colored glass 2.

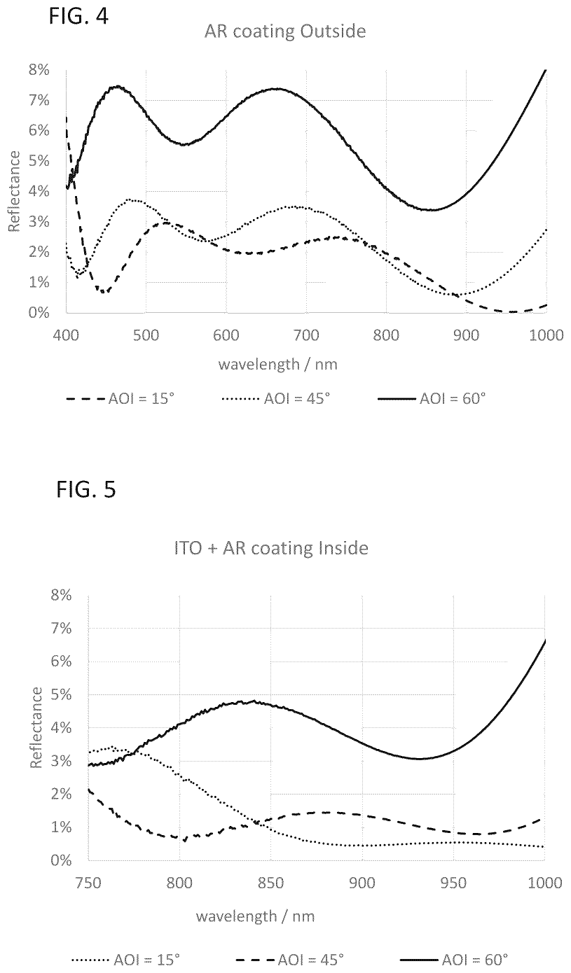

FIG. 4 shows the reflection spectra of an exemplary embodiment including a coating including 7 layers (SiO₂ and Ta₂O₅ in alternation) with a total layer thickness of about 530 nm at different reflection angles.

This exemplary embodiment is optimized for the use of a laser having an emission wavelength in the region of 905 nm. Correspondingly, the reflection spectra in this wavelength range show particularly low reflection. In this context, in this wavelength range, reflection even at a high reflection angle of 60° is only 4%.

FIG. 5 shows the reflection spectra of a second exemplary embodiment. In this exemplary embodiment, the window has a further coating on the reverse side in use. This coating includes an optical interference antireflection coating and an ITO layer. The second exemplary embodiment thus has the construction shown in FIG. 3. Here too, the reflection spectra show particularly low reflection in the wavelength range around 905 nm. In this case, reflection in this wavelength range even at a high reflection angle of 60° is less than 4%.

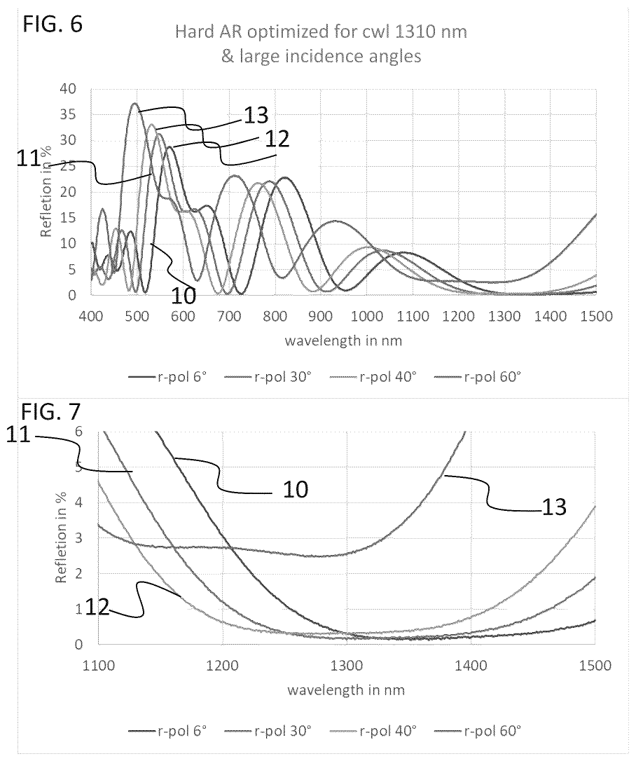

FIG. 6 and FIG. 7 show the reflection spectra of a second exemplary embodiment at different reflection angles. Curve 10 here corresponds to the reflection profile at a reflection angle of 6°, curve 11 to the reflection profile at a reflection angle of 30°, curve 12 to the reflection profile at a reflection angle of 40°, and curve 13 to the reflection profile at a reflection angle of 60°.

On the front side of the window in use, the window has a four-layer antireflection coating (SiₓAl_{y}N_{z}, SiₓAl_{y}O_{z}, SiₓAl_{y}N_{z}, SiₓAl_{y}O_{z}) having a total layer thickness of about 1050 nm. The window is optimized with regard to its transmission and reflection for use with a laser having an emission wavelength of 1310 nm. Thus, the window for wavelengths in the range from 1290 to 1330 nm has particularly low reflection values at all reflection angles examined. Table 1 below gives the average reflection averaged over a wavelength range of 1290 nm to 1300 nm for different reflection angles r-pol.

TABLE 1
Reflection values of the second exemplary embodiment

| | r-pol 6° | r-pol 30° | r-pol 45° | r-pol 60° |
|---|---|---|---|---|
| R_{avg (1290-1330 nm)} | 0.3% | 0.2% | 0.3% | 2.7% |

It becomes clear from Table 1 that reflection at angles up to 450 is largely angle-independent. Even in the case of a large angle of 60°, very low reflection values can be achieved.

In the visible spectral region, all the reflection spectra 10, 11, 12, 13 shown in FIG. 6 have multiple reflection maxima. Depending on the respective design of the coating, these reflection maxima occur in different intensity and/or different wavelength ranges, and hence affect the color impression of the window perceived by the observer.

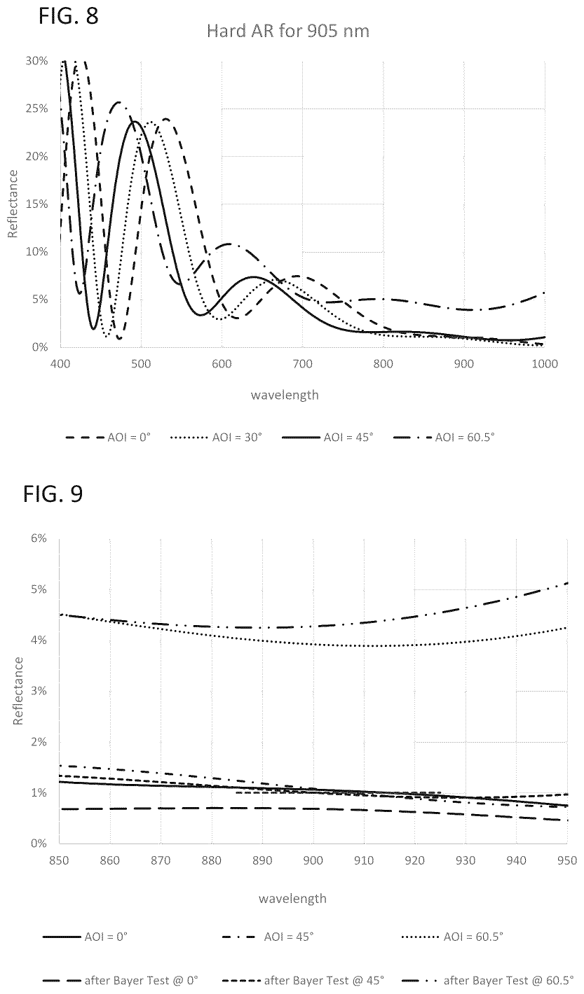

FIG. 8 shows reflection spectra of a third exemplary embodiment at different reflection angles. In the third exemplary embodiment, the substrate glass used was a colored glass having the following composition in cation percent:

The antireflection coating has 4 layers (Si₃N₄, SiAlNₓO_{y}, Si₃N₄, SiAlNₓO_{y}) with a total thickness of about 620 nm and corresponds to an exemplary embodiment according to FIG. 1.

The third exemplary embodiment is particularly suitable as a window for light sources having wavelengths in the range from 890 nm to 920 nm. It becomes clear from FIG. 8 that, in the wavelength range of relevance here from 890 nm to 920 nm, reflection at the measurement angles of 0°, 30° and 45° is virtually identical. In this angle range, reflection is thus largely angle-independent. Even in the case of a large measurement angle of 60.5°, reflection in the corresponding wavelength range is below 5%.

FIG. 9 shows reflection spectra of the third exemplary embodiment before and after the performance of a Bayer test. The Bayer test enables assessment of the mechanical strength of a surface, especially the scratch resistance thereof. It becomes clear from FIG. 9 that reflection after performance of the Bayer test is increased only minimally compared to reflection before the Bayer test. Thus, the reflection spectra after the Bayer test at a measurement angle of 60° have an increase in reflection below 1%; at measurement angles of 0° and 45°, reflection is even increased by less than 0.5%. The window thus shows exceptionally high scratch resistance.

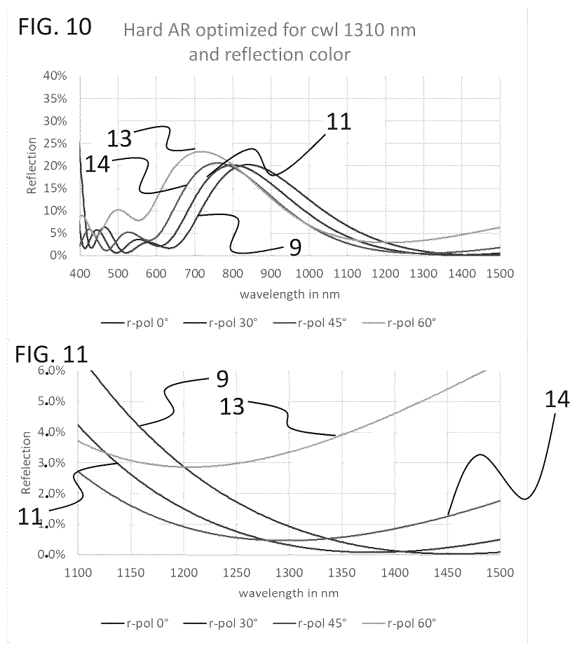

FIGS. 10 and 11 show the reflection spectra of a fourth exemplary embodiment. Reflection was measured here at measurement angles of 0° (curve 9), 30° (curve 11), 45° (curve 14) and 60° (curve 13). The fourth exemplary embodiment has an optical interference coating having 6 layers, where the individual layers have the following composition: SiₓAl_{y}N_{z}, SiₓAl_{y}O_{z}, SiₓAl_{y}N_{z}, SiₓAl_{y}O_{z}, SiₓAl_{y}N_{z}, SiₓAl_{y}O_{z}. The total layer thickness is about 570 nm. The coating has been optimized here with regard to minimum reflection in the wavelength range from 1290 nm to 1330 nm and to reduced reflectivity in the visible wavelength range from about 380 to 780 nm. Like exemplary embodiments 1 to 3 as well, the exemplary embodiment shows largely angle-independent reflection. Table 2 gives the average reflection values for the wavelength range of 1290 nm to 1330 nm.

TABLE 2

| | r-pol 0° | r-pol 30° | r-pol 45° | r-pol 60° |
|---|---|---|---|---|
| R_{avg (1290-1330 nm)} | 0.8% | 0.3% | 0.5% | 3.4% |

The sixth exemplary embodiment was designed with regard to optimal optical properties in the range from 1530 nm and 1570 nm and to a bluish reflection color.

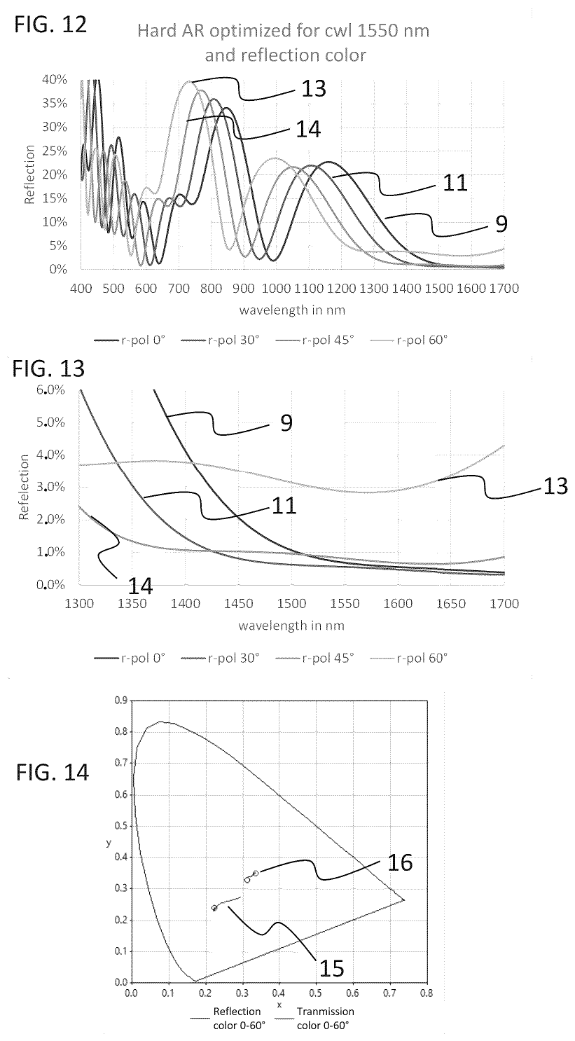

FIGS. 12 and 13 show the reflection spectra at different measurement angles. This exemplary embodiment too, with an optical interference coating having 6 layers with a total layer thickness of about 1124 nm, including the individual layers Si₃N₄, SiₓAl_{y}O_{z}, Si₃N₄, SiₓAl_{y}O_{z}, Si₃N₄, SiₓAl_{y}O_{z}, shows largely uniform reflection characteristics in the relevant wavelength range up to an angle size of 45°. Even at an angle of 60°, average reflection in the relevant wavelength range from 1530 to 1570 nm is below 3%. Table 3 shows average reflection values R_{avg} at different angles.

TABLE 3

| | r-pol 0° | r-pol 30° | r-pol 45° | r-pol 60° |
|---|---|---|---|---|
| R_{avg 1530 1570 nm} | 0.7% | 0.5% | 0.8% | 2.9% |

FIG. 14 shows the shift 15 in the reflection color at angles in the range from 0° to 60° using a CIE 1931 x-y diagram and the shift 16 in the transmission, between 0° and 60°. It becomes clear from FIG. 15 that the window in this exemplary embodiment has a bluish reflection color.

### LIST OF REFERENCE NUMERALS

1 window
2 colored glass
4 front side in use
5 reverse side in use
7 laser beam
8 coating
9 reflection spectrum at 0°
10 reflection spectrum at 6°
11 reflection spectrum at 30°
12 reflection spectrum at 40°
13 reflection spectrum at 60°
14 reflection spectrum at 45°
15 shift in the reflection color between 0° and 60°
16 shift in the transmission color, between 0° and 60°
30 optical interference coating
31, 32, 33, 34 individual layers of the coating 30
40 second optical interference coating
41, 42, 43 individual layers of the coating 40
50 ITO coating

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A window, comprising:
a vitreous substrate pane forming a substrate, the substrate including at least one surface; and
a coating disposed on the at least one surface of the substrate,
wherein at least one of:
(a) the window within a wavelength range from 400 to 700 nm has an average transmittance τ_{avg,400 nm to 700 nm} of less than 15%, where τ_{avg,400 nm to 700 nm} is defined as
$${τ}_{a v ℊ , 400 n m - 700 n m} = \frac{{\int }_{400 n m}^{700 n m} τ d λ}{700 n m - 400 n m} ;$$
and
(b) at any wavelength the window has a spectral transmittance of less than 15%,
wherein the window at at least one wavelength within a wavelength range from 875 nm to 1600 nm has a transmittance of at least 75%.

2. The window according to claim 1, wherein the window has a thickness of at least 0.5 mm and at most 12 mm.

3. The window according to claim 2, wherein the thickness is at least 2 mm and at most 6 mm.

4. The window according to claim 1, wherein the coating includes at least one layer including at least one of: an oxide; a nitride; an oxynitride of a metal; and an oxynitride of a semimetal.

5. The window according to claim 1, wherein the coating has a thickness of at least 125 nm.

6. The window according to claim 5, wherein the thickness of the coating is at least 1500 nm.

7. The window according to claim 1, wherein the window at at least one wavelength within a wavelength range from 875 nm to 1600 nm has a transmittance of at least 85%.

8. The window according to claim 1, wherein the window at at least one wavelength within a wavelength range from 875 nm to 1600 nm has a transmittance of at least 97%.

9. The window according to claim 1, wherein at least one of:
(a) a spectral reflectance ρ_{λ} at at least one wavelength within a range between 875 nm and 1600 nm is not more than 14%;
(b) a spectral reflectance ρ_{λ} of the window at at least one wavelength in a range between 875 nm and 1600 nm is at least 2 percentage points lower than a spectral reflectance of the at least one surface of the substrate; and
(c) an average spectral reflectance ρₐᵥₑ of a surface of the window within a wavelength range between at least one of 1530 nm and 1570 nm, 880 and 930 nm, and 1300 to 1340 nm is at least one of: (i) not more than 4% for a plurality of measurement angles between 0° and 45°, and (ii) not more than 7% determined for a measurement angle of 60°.

10. The window according to claim 1, wherein at least one of:
(a) an average transmittance T_{avg} within a wavelength range between at least one of 1530 nm and 1570 nm, 880 and 930 nm, and 1300 to 1340 nm is at least one of (i) at least 90% for a measurement angle of 0°, (ii) at least 89% for a measurement angle of 45°, (iii) at least 87% for a measurement angle of 60°, and (iv) at least 84% at a measurement angle of 70°; and
(b) a difference in a spectral transmittance between s- and p-polarized light, ΔT_{s-p,pol}, of the window at at least one wavelength within a range between 875 nm and 1600 nm and at least one measurement angle from 30 to 60° is less than 3 percentage points.

11. The window according to claim 1, wherein the substrate includes a glass having a coefficient of thermal expansion (−30° C. to 70° C.) between 3*10⁻⁶/K and 14*10⁻⁶/K.

12. The window according to claim 1, wherein a haze value by a Bayer test is elevated by not more than 4%.

13. The window according to claim 1, a phototopic reflection color of the window under CIE 1931 is x 0.20-0.4 y 0.20-0.4 for an angle range from 0 to 30°.

14. The window according to claim 1, wherein the average transmittance τ_{avg,400 nm to 700 nm} is less than 10%.

15. The window according to claim 1, wherein the spectral transmittance is less than 10%.

16. The window according to claim 1, wherein the spectral transmittance is less than 5%.

17. The window according to claim 1, wherein the spectral transmittance is less than 1%.

18. The window according to claim 1, wherein the transmittance is at least 80%.

19. A method of using a window, the method comprising the steps of:
providing that the window includes:
a vitreous substrate pane forming a substrate, the substrate including at least one surface; and
a coating disposed on the at least one surface of the substrate,
wherein at least one of:
(a) the window within a wavelength range from 400 to 700 nm has an average transmittance τ_{avg,400 nm to 700 nm} of less than 15%, where τ_{avg,400 nm to 700 nm} is defined as
$${τ}_{a v ℊ , 400 n m - 700 n m} = \frac{{\int }_{400 n m}^{700 n m} τ d λ}{700 n m - 400 n m} ;$$
and
(b) at any wavelength the window has a spectral transmittance of less than 15%,
wherein the window at at least one wavelength within a wavelength range from 875 nm to 1600 nm has a transmittance of at least 75%; and
using the window as a cover glass.

20. The method according to claim 19, wherein the cover glass is for a laser, for a laser as a part of a LIDAR system, for an imaging system, or for an imaging system of a device configured for 3D surveying of an environment or for measuring speed.
